(19) United States
(12) Patent Application Publication
(10) Pub. No.: US 2007/0295967 A1
(43) Pub. Date: Dec. 27, 2007

(54) ACTIVE MATRIX TFT ARRAY SUBSTRATE AND METHOD OF MANUFACTURING THE SAME

(75) Inventors: Kazuyuki HARADA, Kumamoto (JP); Nobuaki Ishiga, Kumamoto (JP); Kazunori Inoue, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/759,000

(22) Filed: Jun. 6, 2007

(30) Foreign Application Priority Data
Jun. 27, 2006 (JP) 2006-176020

(51) Int. Cl. H01L 29/06; H01L 21/336

(52) U.S. Cl. 257/72; 438/158; 257/E29.003; 257/E21.414

(57) ABSTRACT

An active matrix TFT array substrate includes a gate electrode and a gate line formed from a first metal film over a transparent insulating substrate, a gate insulating film to cover the gate electrode and gate line, a semiconductor layer formed over the gate insulating film, a source electrode and a drain electrode formed over the semiconductor layer and a pixel electrode formed from a transparent conductive film. Either of the source or the drain electrode is formed from the transparent conductive film and the active matrix TFT array substrate further comprises a second metal film thereover mainly including one of Al, Cu and Ag.

### BACKGROUND OF THE INVENTION

1. Field of the Invention

The present invention relates to an active matrix TFT array substrate, and particularly to an active matrix TFT array substrate for a liquid crystal display.

2. Description of Related Art

In recent years, in a field of display devices using semiconductor devices, liquid crystal displays characterized by reduced energy and space are rapidly becoming common in place of conventional CRTs. In the liquid crystal display, a plurality of electrodes, lines and devices are provided over a transparent insulating substrate. To be more specific, active matrix TFT array substrates are widely used in which switching devices such as thin film transistors (TFTs) having scanning and signal lines, gate, source and drain electrodes are provided in array and an independent video signal is applied to electrode of each display pixel.

On the other hand, to manufacture this active matrix TFT array substrate, many processes are required. Thus there are problems in productivity including increasing number of manufacturing equipment and rate of defective occurrence. As disclosed in Japanese Unexamined Patent Application Publication No. 10-268353, conventionally a manufacturing method that performs 5 photolithography processes (hereinafter referred to as a 5 mask process) has been common. In order to improve the productivity, a manufacturing method that performs 4 photolithography processes (hereinafter referred to as a 4 mask process) is disclosed (see Japanese Unexamined Patent Application Publication No. 2003-297850 and 2005-283689).

However in the 4 mask process as explained in Japanese Unexamined Patent Application Publication No. 2003-297850, a control of a channel length which is a width of a semiconductor active layer, or a distance of source and drain electrodes, has been extremely difficult. This is because that a desired channel length cannot be obtained unless controlling all of uniformity in resist film thickness and resist film quality before the exposure, optimum light exposure in a halftone exposure, uniformity of resist development and uniformity in resist removing process. Therefore, TFTs with different channel length exist in the same liquid crystal panel and a defect is generated from the variation of TFT characteristics, thereby decreasing the productivity.

Moreover, along with increasing size and higher-resolution of the liquid crystal display, problems are emerging in signal delay due to longer scanning and signal lines and narrower line width. Therefore, for electrode and line material, Al which has low resistance electrically has often been used. For the Al electrode and line, favorable electric contact characteristics cannot be obtained with an ohmic contact film of lower layer semiconductor and an upper layer transparent electrode layer formed of ITO or the like. To resolve this, it is necessary to form a high-melting point metal film such as Ti, Cr and Mo in a connection portion between an Al film and an ohmic contact film or a transparent electrode layer to form 3 layer structure of Cr/Al/Cr, for example. In order to form this, each of the upper layer Cr film, Al film, and lower layer Cr film is etched, thus total of 3 etchings are required usually. On the other hand in the 4 mask process, as the abovementioned 3 layers remaining over the semiconductor active layer are removed, further 3 etchings are required. This even increases the number of processes and decreases productivity. Moreover, the repetitive etching causes problems such as defective size control in channel length, electrode and line, higher resistance and disconnections in lines by over-etching.

### SUMMARY OF THE INVENTION

The present invention is made in consideration of the above situation and aims to provide an active matrix TFT array substrate with excellent reliability and productivity.

According to an aspect of the present invention, there is provided an active matrix TFT array substrate that includes a gate electrode and a gate line formed from a first metal film over a transparent insulating substrate, a gate insulating film to cover the gate electrode and gate line, a semiconductor layer formed over the gate insulating film, a source electrode and a drain electrode formed over the semiconductor layer and a pixel electrode formed from a transparent conductive film. Either of the source or the drain electrode is formed from the transparent conductive film and the active matrix TFT array substrate further comprises a second metal film thereover mainly including one of Al, Cu and Ag.

According to another aspect of the present invention, there is provided a method of manufacturing an active matrix TFT array substrate that includes forming a gate electrode and a gate line from a first metal film formed over a transparent insulating substrate by a first photolithography process, sequentially forming a gate insulating film and a semiconductor layer to cover the gate electrode, patterning the semiconductor layer by a second photolithography process, sequentially forming a transparent conductive film and a second metal film mainly including one of Al, Cu or Ag, forming a resist pattern thinner than other area to at least a part of a pixel electrode, etching the second metal film, the transparent conductive film and an ohmic contact film of the semiconductor layer to form a TFT channel and etching the second metal film exposed by removing the thin resist pattern by a third photolithography process, forming a passivation film, and forming a contact hole to the gate insulating film and the passivation film penetrating to a surface of the first metal film and a contact hole to the passivation film penetrating to a surface of the transparent conductive film or the second metal film by a forth photolithography process.

The present invention is able to provide an active matrix TFT array substrate with excellent reliability and productivity.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view showing an active matrix TFT array substrate according to a first embodiment;

FIG. 2 is a cross-sectional diagram showing the active matrix TFT array substrate according to the first embodiment;

FIG. 3 is a flowchart illustrating a manufacturing process of the active matrix TFT array substrate according to the first embodiment;

FIGS. 4A to 4G are cross-sectional diagrams illustrating the manufacturing process of the active matrix TFT array substrate according to the first embodiment;

FIG. 5 is a plan view showing an active matrix TFT array substrate according to a second embodiment;

FIG. 6 is a cross-sectional diagram showing the active matrix TFT array substrate according to the second embodiment;

FIGS. 7A to 7G are cross-sectional diagrams illustrating a manufacturing process of the active matrix TFT array substrate according to the second embodiment; and

FIGS. 8A and 8B are cross-sectional diagrams showing a source terminal pad according to the present invention.

### DESCRIPTION OF THE PREFERRED EMBODIMENTS

An embodiment of an active matrix TFT array substrate used in a liquid crystal display device according to the present invention is described hereinafter in detail. However the present invention is not limited to the embodiments below. Furthermore, the drawing figures and explanations are omitted or simplified in the interest of clarity.

### First Embodiment

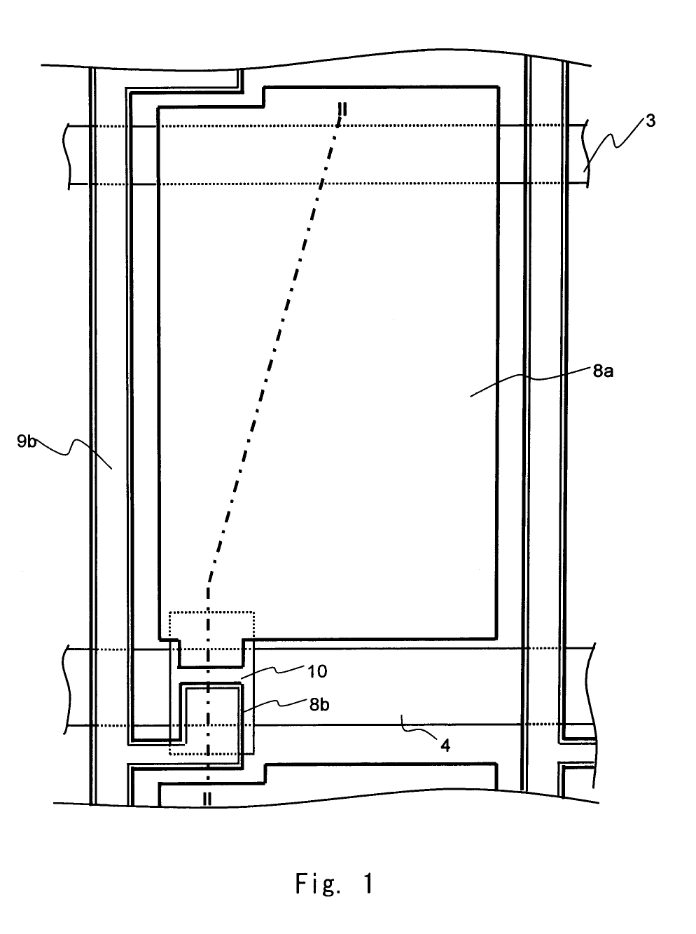

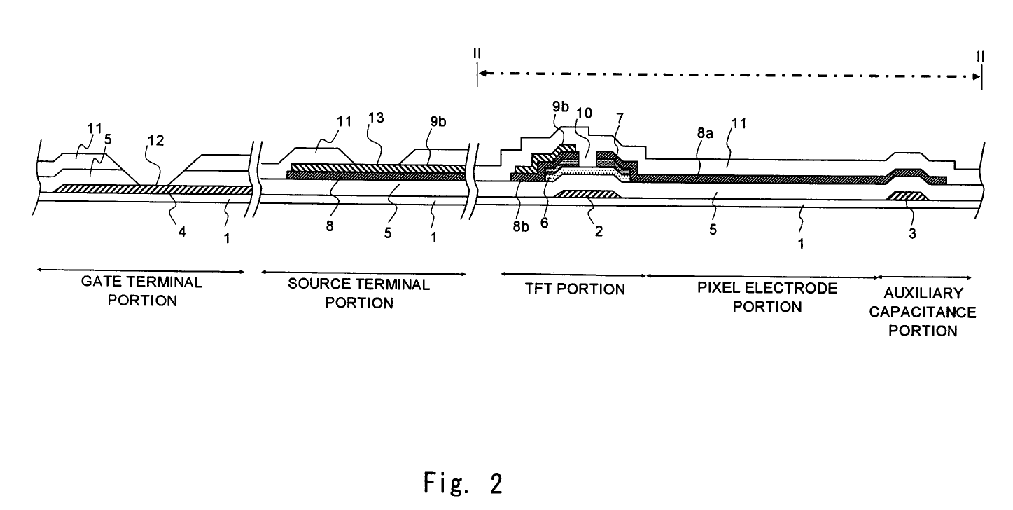

FIG. 1 is a plan view of one pixel in an image display area of an active matrix TFT array substrate according to a first embodiment. FIG. 2 is a cross-sectional diagram taken along the line II-II of FIG. 1 and also across-sectional diagram of a signal input terminal portion (not shown in FIG. 1) formed outside the image display area of the active matrix TFT array substrate. As the signal input terminal portion, a gate terminal input with a scanning signal and a source terminal input with a video signal are illustrated.

The active matrix TFT array substrate in FIGS. 1 and 2 includes a transparent insulating substrate 1, gate electrode 2, auxiliary capacitance electrode 3, gate line 4, gate insulating film 5, semiconductor active film 6, ohmic contact film 7, drain electrode-cum-pixel electrode 8a, source electrode 8b, source line 9b, TFT channel 10, passivation film (interlayer dielectric) 11, gate terminal pad 12 and source terminal pad 13.

As for the transparent insulating substrate 1, a transparent insulating substrate such as glass substrate or silica glass can be used. The thickness of the insulating substrate 1 may be any but preferably not more than 1.1 mm in order to reduce the thickness of a liquid crystal display. If the insulating substrate 1 is too thin, the substrate is distorted due to a thermal history of processes thereby decreasing patterning accuracy. Thus the thickness of the insulating substrate 1 needs to be selected in consideration over the process to be used. Further, if the insulating substrate 1 is made from brittle fracture material such as a glass, edge face of the substrate is preferably chamfered so as to prevent any foreign matters from getting inside. Further, it is preferable that a notch is created at a part of the transparent insulating substrate 1 to identify the orientation of the substrate for easier process management.

The gate electrode 2, auxiliary capacitance electrode 3 and gate line 4 are formed over the transparent insulating substrate 1. The gate electrode 2, auxiliary capacitance electrode 3 and gate line 4 are formed from the same first metal film. As for the first metal film, a metal film mainly containing Al, Cu, Mo, Cr, Ti, Ta and W or the like having a thickness of approx. 100 to 500 nm may be used.

The gate insulating film 5 is formed over the transparent insulating substrate 1, gate electrode 2, auxiliary capacitance electrode 3 and gate line 4. As for the gate insulating film 5, a silicon nitride film (SiNₓ), a silicon oxide film (SiOₓ), a silicon nitric-oxide film (SiOₓN_{y}) and a laminated film thereof having a thickness of approx. 300 to 600 nm may be used. If the film is thin, it is likely to generate a short-circuit in a crossover of the gate and source lines, thus the film preferably has a thickness of more than the gate line 4 and auxiliary capacitance electrode 3 or the like. On the other hand if the film thickness is thick, an ON current of TFT decreases and thus the display characteristic decreases.

The semiconductor active film 6 is formed over the gate insulating film 5. As for the semiconductor active film 6, an amorphous silicon (a-Si) film or a polycrystalline silicon (p-Si) film having a thickness of approx. 100 to 300 nm may be used. If the film is thin, the film is likely to disappear at a dry etching of the ohmic contact film 7, which is described later in detail. On the other hand, if the film is thick, the ON current of TFT decreases.

If a-Si film is used for the semiconductor active film 6, an interface to the a-Si film of the gate insulating film 5 is preferably SiNₓ or SiOₓN_{y} in light of controllability and reliability of a threshold voltage (Vₜₕ) of the TFT, which is a gate voltage to make the TFT conductive. On the other hand if a p-Si film is used for the semiconductor active film 6, an interface to the p-Si film of the gate insulating film 5 is preferably SiOₓ or SiOₓN_{y} in light of controllability and reliability of Vₜₕ of the TFT, which is a gate voltage to make the TFT conductive.

The ohmic contact film 7 is formed over the semiconductor active film 6. As for the ohmic contact film 7, an n type a-Si film or an n type p-Si film can be used, which are a-Si or p-Si having a thickness of approx. 20 to 70 nm doped with a small amount of P.

The drain electrode-cum-pixel electrode 8a and source electrode 8b are formed over the ohmic contact film 7 and are connected to the semiconductor active film 6 with the ohmic contact film 7 interposed therebetween. The drain electrode-cum-pixel electrode 8a and source electrode 8b are formed from the same transparent conductive film 8. As for the transparent conductive film 8, In₂O₃, SnO₂, ITO which is a mixture of In₂O₃ and SnO₂, IZO which is a mixture of In₂O₃ and ZnO, or ITZO which is a mixture of In₂O₃, SnO₂ and ZnO can be used.

The source line 9b is formed over the source electrode 8b and extends to a source terminal (not shown). The source line 9b is formed from a second metal film and a similar material as the first metal film can be used.

The passivation film 11 is formed over the source line 9b and drain electrode-cum-pixel electrode 8a or the like. As for the passivation film 11, a similar material as the gate insulating film 5 can be used.

The gate terminal pad 12 is formed to expose the gate line 4 by a contact hole penetrating the passivation film 11 and gate insulating film 5. Furthermore, the source terminal pad 13 is formed to expose the source line 9b by a contact hole penetrating the passivation film 11.

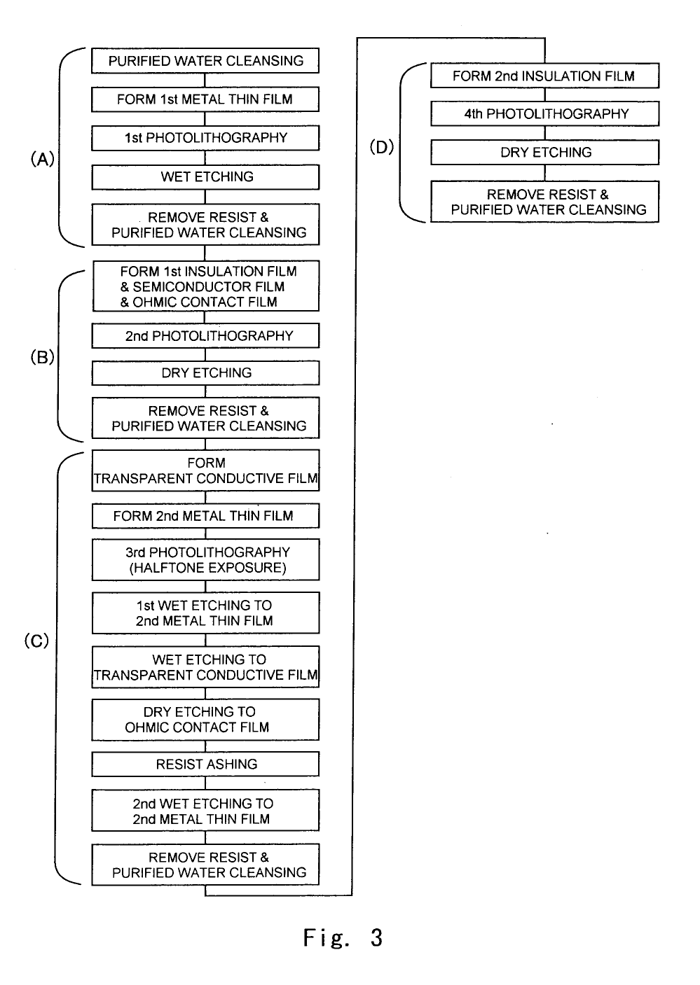

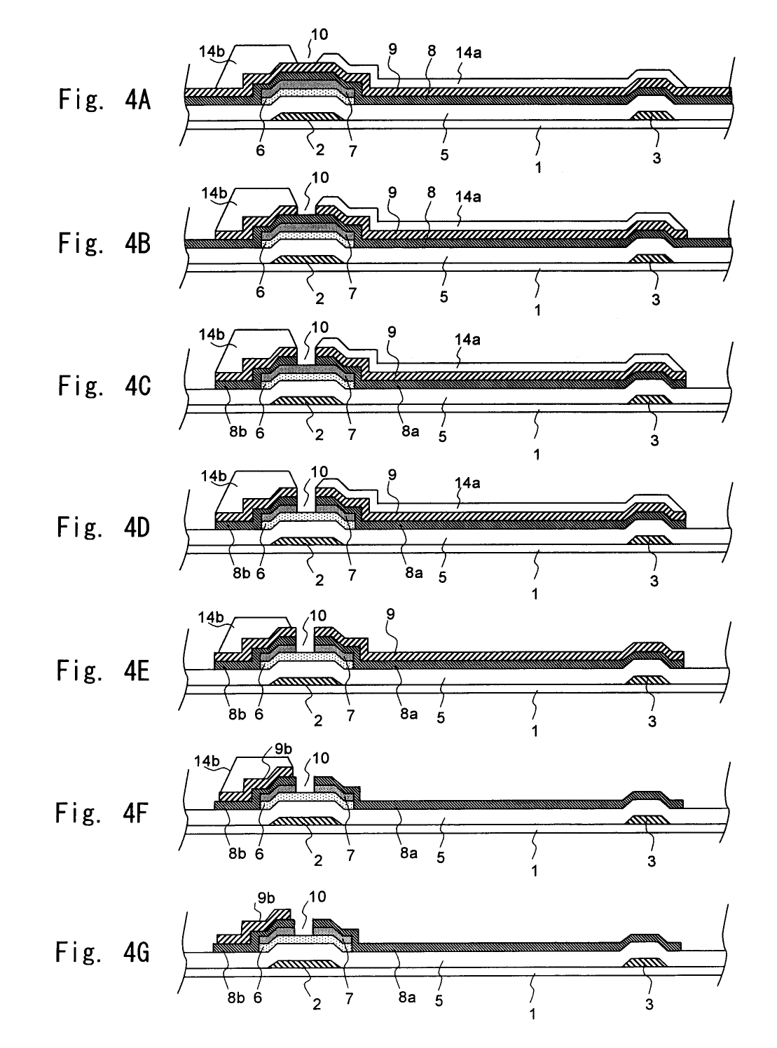

Next, a manufacturing method of an active matrix TFT array substrate according to the first embodiment is described hereinafter with reference to FIGS. 3 and 4A to 4G. Note that the example below is a typical example and it is needless to say that other manufacturing method can be employed without departing from the scope and spirit of the invention.

As shown in (A) of FIG. 3, firstly the surface of the insulating substrate 1 is cleansed by hot sulfuric acid and purified water. Over the insulating substrate 1, the first metal film for forming the gate electrode 2, auxiliary capacitance electrode 3 and gate line 4 is formed by a sputtering and vacuum deposition method or the like. Next, by a first photolithography process, a resist pattern is formed in the region to form the gate electrode 2, auxiliary capacitance electrode 3 and gate line 4 over the first metal film. Next, the area not covered by the resist pattern is removed by a wet etching to the first metal film. Lastly, a photosensitive resist is removed and cleansed using purified water. This is how the gate electrode 2, auxiliary capacitance electrode 3 and gate line 4 are formed.

As a preferred embodiment, Al-0.2 mol % Nd alloy film, which is pure Al added with 0.2 mol % Nd, is formed to have a thickness of 200 nm by a DC magnetron sputtering method using known Ar gas. Next, after forming a resist pattern on the Al-Nd alloy film, the Al-Nd alloy film is etched using a solution including known phosphorus acid+nitric acid. Lastly, the resist pattern is removed to form the gate electrode 2, auxiliary capacitance electrode 3 and gate line 4.

Next as shown in (B) of FIG. 3, thin films for forming the gate insulating film 5 formed of SiNₓ, SiOₓ and SiOₓN_{y} or the like, semiconductor active film 6 formed of a-Si or p-Si and ohmic contact film 7 formed of n type a-Si or n type p-Si are consecutively formed by a plasma CVD (Chemical Vapor Deposition) method. Then, by a second photolithography process, a resist pattern is formed in the region to form TFTs and the source line 9, in post-process, over the CVD film. To be precise, the resist pattern is formed in the region slightly larger than the region to form the source line 9. Furthermore, a TFT forming area and the source line 9 forming area are continued. Next, by a dry etching to the thin films for the semiconductor active film 6 and ohmic contact film 7, the region not covered by the resist pattern is removed. Lastly, a photosensitive resist is removed and cleansed using purified water. This is how the semiconductor active film 6 and ohmic contact film 7 are formed. Note that the gate insulating film 5 remains all over.

As a preferred embodiment, by a CVD method, a SiN film is formed to have a thickness of 400 nm as a thin film for the gate insulating film 5, an a-Si film is formed to have a thickness of 150 nm as a thin film for the semiconductor active film 6 and an n type a-Si film is formed to have a thickness of 30 nm which is added with P as a dopant as a thin film for the ohmic contact film 7. Next, after forming the resist pattern over the CVD film, the thin films for the semiconductor active film 6 and ohmic contact film 7 are dry etched using known fluorine gas (for example mixed gas of SF₆ and O₂ or CF₄ and O₂). Lastly, the resist pattern is removed to form the semiconductor active film 6 and ohmic contact film 7.

Next, as shown in (C) of FIG. 3, the transparent conductive film 8 for forming the drain electrode-cum-pixel electrode 8a and source electrode 8b and the second metal film 9 shown in FIG. 4 for forming the source line 9b are consecutively formed by a sputtering and vacuum deposition method or the like. Then, by a third photolithography process, the drain electrode-cum-pixel electrode 8a, source electrode 8b, source line 9b and TFT channel 10 are formed.

As a preferred embodiment, by a DC magnetron sputtering method using known Ar gas, an ITO film is formed to have a thickness of 10 nm as the transparent conductive film and an Al-0.2 mol % Nd alloy film is formed to have a thickness of 200 nm as the second metal film. Hereinafter, the third photolithography process is described in detail with reference to FIGS. 4A to 4G.

In order to be the state of FIG. 4A, a novolac resin based positive resist is coated to have an approx. 1.6 μm thickness by a spin coater and pre-baked at 120 degrees Celsius for about 90 seconds. Next, a first exposure is performed in order to form a resist pattern 14b for forming the source line 9b and source electrode 8b. Then, a second exposure is performed to form a resist pattern 14a for forming the drain electrode-cum-pixel electrode 8a. As the resist pattern 14a is not completely removed but remains with thin film, the second exposure is a half exposure with approx. 40% light exposure of the first exposure.

After performing the two-step exposure and development by an organic alkaline developer, by performing a post-bake at 120 degrees Celsius for about 180 seconds, the resist patterns 14a and 14b having different thickness are formed as shown in FIG. 4A. The thick resist pattern 14b is formed over the second metal film which remains after the third photolithography. On the other hand, the thin resist pattern 14a is formed over the second metal film which is removed in the third photolithography process. The resist pattern to have the resist pattern 14a of approx. 0.4 μm thickness and the resist pattern 14b of approx. 1.6 μm thickness is used in the first embodiment. Note that in this embodiment, the abovementioned two-step exposure is performed, however it may be one-shot exposure using a halftone pattern mask to have a light transmittance amount of 40% for the pattern positioned to the resist pattern 14a. For the halftone pattern mask, a filter film for reducing the light transmittance amount of wavelength area (usually 350 to 450 nm) used for an exposure may be formed to a desired portion of the mask or a slit-shaped pattern may be formed to a desired portion of the mask using diffraction phenomenon. By the one-shot exposure using the halftone pattern mask, the manufacturing process can be simplified.

Next, with the resist pattern shown in FIG. 4A, using a known solution including phosphorus acid and nitric acid, the Al-Nd film, which is the second metal film 9, is etched to be the state of FIG. 4B. Then, using a known solution including hydrochloric acid and nitric acid, the ITO film, which is the transparent conductive film 8, is etched to be the state of FIG. 4C. Here instead of the ITO film, when using an amorphous ITO film, IZO film or ITZO film, oxalic acid which is weak acid can be used to etch, thus there is no danger of etching other line and electrode, thereby improving productivity. Then, using known fluorine gas, the ohmic contact film 7 is etched to be the state of FIG. 4D. Then, the TFT channel 10 is formed between the resist patterns 14a and 14b. In the present invention, the process to remove the thin resist pattern 14a is performed after forming the TFT channel 10, thus it is easy to control the channel length of the TFT. To be more specific, as compared to a conventional manufacturing method, there is less strictness required in controlling uniformity of the resist film thickness and resist film quality before the exposure, optimum light exposure in the halftone exposure, uniformity of resist development and uniformity in resist removing process, thereby improving the productivity.

Next, the resist pattern 14a is removed by a resist ashing using known oxygen plasma to be the state of FIG. 4E. At this time, as the resist pattern 14b is thicker than the resist pattern 14a, the resist pattern 14b is not completely removed but remains. Then, using a known solution including phosphorus acid and nitric acid, the Al-Nd film, which is the second metal film 9 and exposed by removing the resist pattern 14a, is etched to be the state of FIG. 4F. Next, the resist pattern 14b is removed to be the state of FIG. 4G. As described above, by the third photolithography process, the drain electrode-cum-pixel electrode 8a, source electrode 8b, source line 9b and TFT channel 10 are formed.

Next, as shown in (D) of FIG. 3, the thin film for forming the passivation film 11 formed of SiNₓ, SiOₓ and SiOₓN_{y} or the like is formed by a plasma CVD method. Next, by a fourth photolithography process, a resist pattern is formed over the CVD film. Then, by performing a dry etching to the thin film for the passivation film 11 and gate insulating film 5, the region not covered by the resist pattern is removed. Lastly, a photosensitive resist is removed and cleansed using purified water. This is how a contact hole penetrating at least to the surface of the first metal film and a contact hole penetrating to the surface of the second metal film 9 or transparent conductive film 8 are formed.

As a preferred embodiment, a SiNₓ film is formed to have a thickness of 300 nm as the thin film for the passivation film 11. Next, after forming a resist pattern over the CVD film, the thin film for passivation film 11 is dry etched using known fluorine gas (for example mixed gas of SF₆ and O₂ or CF₄ and O₂). Lastly, the resist pattern is removed to form the gate terminal portion contact hole 12 and source terminal portion contact hole 13 shown in FIG. 2.

The active matrix TFT array substrate manufactured as above is bonded with an opposing substrate (not shown) having a color filter and opposing electrode as a pair of substrates with a spacer interposed therein. A liquid crystal is injected between the pair of substrates. By mounting the liquid crystal panel having the liquid crystal layer held therebetween to aback light portion, a liquid crystal display device is manufactured.

### Second Embodiment

Next, an embodiment different from the TFT active matrix substrate of the first embodiment is described hereinafter. In the explanation below, components identical to those in the first embodiment are denoted by reference numerals identical therein with detailed description omitted as appropriate.

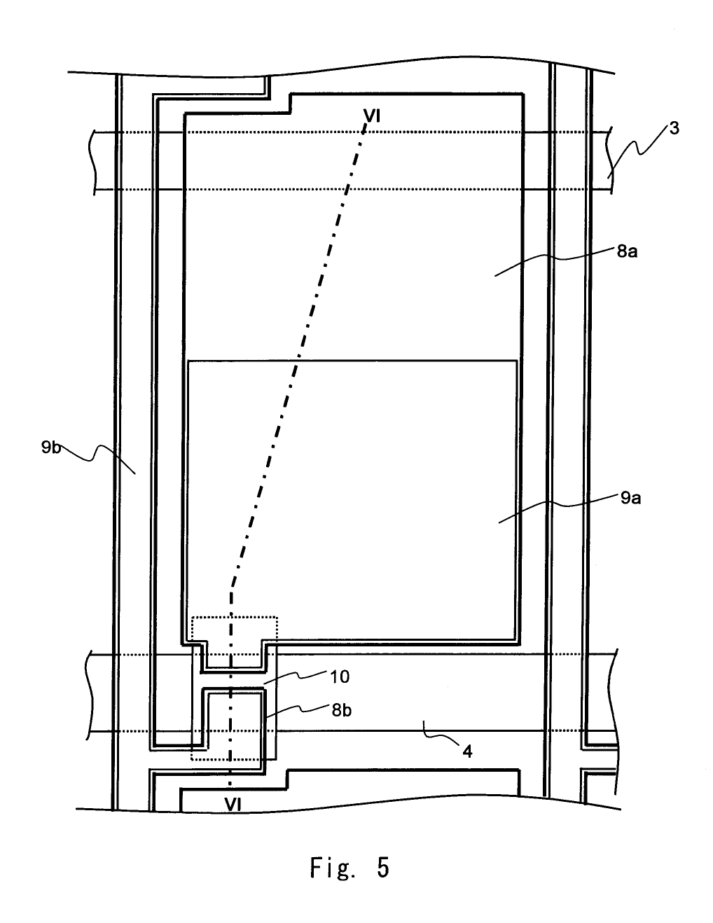

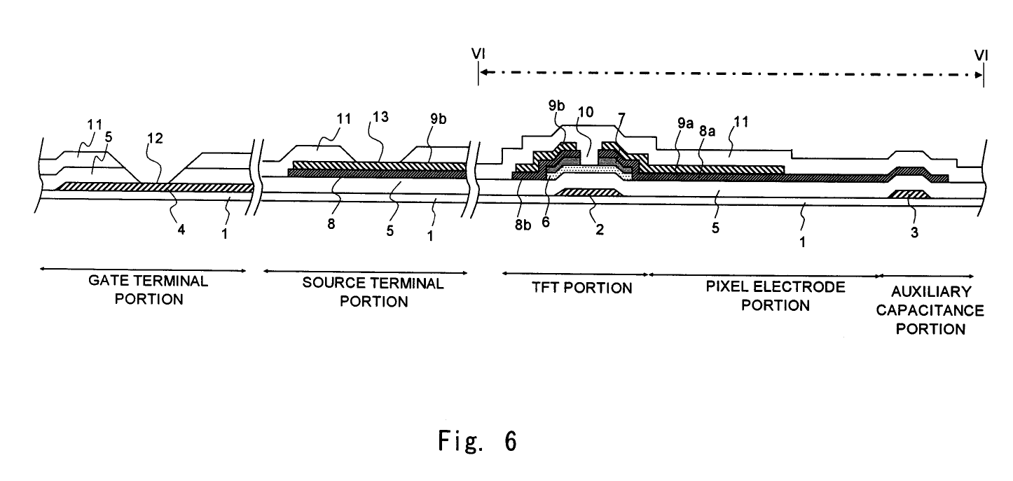

FIG. 5 is a plan view of one pixel in an image display area of an active matrix TFT array substrate according to a second embodiment. FIG. 6 is a cross-sectional diagram taken along the line VI-VI of FIG. 5 and also across-sectional diagram of a signal input terminal portion (not shown in FIG. 5) formed outside the image display area of the active matrix TFT array substrate. Basic components of the TFT active matrix substrate according to the second embodiment excluding the following difference are identical to the TFT active matrix substrate according to the first embodiment.

In the second embodiment, the difference from the first embodiment is that a pixel reflective electrode 9a is formed partially over the drain electrode-cum-pixel electrode 8a. The pixel reflective electrode 9a is formed from the second metal film 9, which is same as the source electrode 9a. The TFT active matrix substrate according to the second embodiment is used for a transflective liquid crystal display. Note that a part or all of the passivation film 11 over the pixel reflective electrode 9a and pixel transmittance portion (the region over the drain electrode-cum-pixel electrode 8a where the pixel reflective electrode 9a is not formed) may be removed. By removing the passivation film 11, light reflective and light transmittance characteristics are improved.

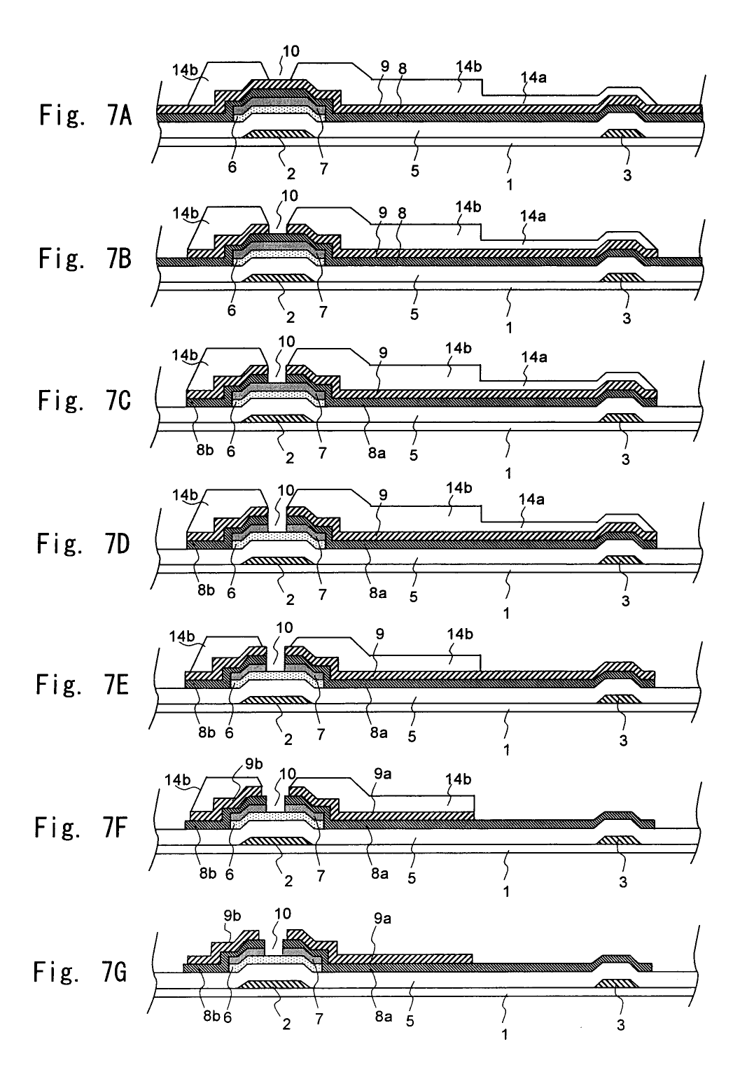

The manufacturing method of the TFT active matrix substrate according to the second embodiment is basically same as the manufacturing method of the TFT active matrix substrate according to the first embodiment except for the third photolithography process to form the pixel reflective electrode 9a. Hereinafter, the third photolithography process is described in detail with reference to FIGS. 7A to 7G.

The resist patterns 14a and 14b having different thickness are formed as shown in FIG. 7A by the similar method as the first embodiment. The thick resist pattern 14b is formed over the second metal film which remains after the third photolithography. On the other hand, the thin resist pattern 14a is formed over the second metal film which is removed in the third photolithography process. To be more specific, the resist pattern to have the resist pattern 14a of approx. 0.4 μm thickness and the resist pattern 14b of approx. 1.6 μm thickness is used.

Next, with the resist pattern shown in FIG. 7A, using a known solution including phosphorus acid and nitric acid, the Al-Nd film which is the second metal film 9 is etched to be the state of FIG. 7B. Then, using a known solution including hydrochloric acid and nitric acid, the ITO film which is the transparent conductive film 8 is etched to be the state of FIG. 7C. Then, using known fluorine gas, the ohmic contact film 7 is etched to be the state of FIG. 7D. This is how the TFT channel 10 is formed. In the present invention, the process to remove the thin resist pattern 14a is performed after forming the TFT channel 10, thus it is easy to control the channel length of the TFT. To be more specific, as compared to a conventional manufacturing method, there is less strictness required in controlling uniformity of the resist film thickness and resist film quality before the exposure, optimum light exposure in the halftone exposure, uniformity of resist development and uniformity in resist removing process, thereby improving the productivity.

Next, the resist pattern 14a is removed by a resist ashing using known oxygen plasma to be the state of FIG. 7E. At this time, as the resist pattern 14b is thicker than the resist pattern 14a, the resist pattern 14b is not completely removed but remains. In the second embodiment, unlike the first embodiment, the resist pattern 14b remains in the region over the second metal film 9 where the pixel reflective electrode 9a is formed. Then, using a known solution including phosphorus acid and nitric acid, the Al-Nd film, which is the second metal film 9 and exposed by removing the resist pattern 14a, is etched to be the state of FIG. 7F. Next, the resist pattern 14b is removed to be the state of FIG. 7G. As described above, by the third photolithography process, in addition to the drain electrode-cum-pixel electrode 8a, source electrode 8b, source line 9b and TFT channel 10, pixel reflective electrode 9a are formed.

As explained in the first and second embodiments, the process to remove the thin resist pattern 14a is performed after forming the TFT channel 10, thus it is easy to control the channel length of the TFT. Thus variations in channel length in the same liquid crystal panel can be reduced, meaning that variations in TFT characteristics can be reduced, and the productivity is improved. Especially as in the second embodiment, by remaining the second metal film 9 over the drain electrode, the thickness of the resist over the drain electrode and source electrode can be uniformed. That is, it is not necessary to use the halftone exposure near the TFT channel and the control of channel length of the TFT is further facilitated.

Moreover, as described above, when using the metal film mainly including Al for electrodes and lines, it is necessary to form a high-melting point metal film such as Ti, Cr and Mo in the connection portion between the Al film, a lower layer ohmic contact film and upper layer transparent electrode layer to have 3 layer structure of Cr/Al/Cr, for example. In the active matrix TFT array substrate according to the present invention, as explained in the first and second embodiments, since the transparent conductive film 8 is formed between the Al alloy film, which is the second metal film 9, and lower layer ohmic contact film 7, an interdiffusion of Al and Si can be prevented and also the high-melting point metal, a lower layer of Al film, is unnecessary. Note that AlOₓ, which increases contact resistance between the Al film and a transparent conductive film such as ITO, IZO and ITZO, is formed when forming a transparent conductive film on the Al film and not formed when forming the Al film on the transparent conductive film. That is, the contact resistance can be reduced by the configuration of the present invention and contact characteristic can be improved. On the other hand, on the first and second metal film 9 for forming the gate electrode or the like, the transparent conductive film 8 is not formed, thus the high-melting point metal, which is an upper layer of the Al film, is unnecessary. That is, a metal film single layer structure mainly including Al can be formed. This largely simplifies the manufacturing process as compared to the conventional 3 layer structure and the productivity is improved. Needless to say, in the present invention, a high-melting point metal may be formed between the Al film and transparent conductive film in terms of adherence, contact resistance and corrosiveness or the like.

In the first and second embodiment, the first and second metal films are the Al-Nd alloy film but by using Cr, Mo or a metal film mainly including these components instead of the Al-Nd alloy film, the reliability is improved. Moreover, as for the Al-Nd alloy film which is the second metal film, by adding one or more kinds of group 8 element such as Fe, Co and Ni instead of Nd, it is possible to prevent ITO reductive corrosion in an alkaline developer in the state in which the Al and ITO films are electrically connected and thus productivity is improved. Furthermore, similar advantageous effects can be obtained when adding N and it is further effective when adding together with group 8 element.

Furthermore, a metal film mainly including Cu, which has lower resistance than Al, can be used for the second metal film 9. This enables to further increase the size and the resolution of the liquid crystal display. By adding Mo to Cu, adherence can be improved. With a Cu film, it is difficult to control the etching and cross-sectional shape for both sides of the line is not favorable, thus it is especially difficult to control channel length. With the present invention, the control of the channel length can be facilitated even when using the Cu film.

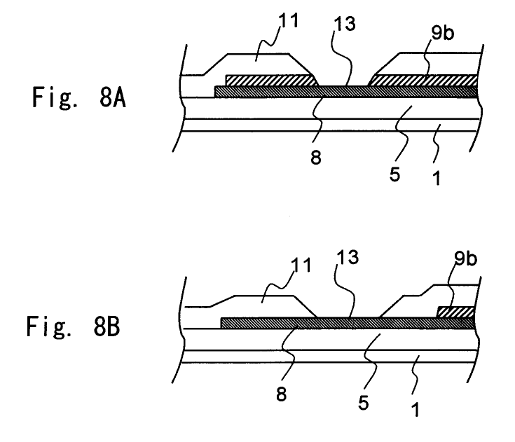

Furthermore, a metal film mainly including Ag, which has lower resistance and better reflection characteristic than Al, can be used for pixel reflective electrode 9a, that is the second metal film 9. This creates a transflective liquid crystal display with excellent optical and electrical characteristics. For example, when applying an Ag film to the manufacturing method of the source line disclosed in Japanese Unexamined Patent Application Publication No. 10-268353, the Ag film for the source line could disappear by plasma at a dry etching to form a contact hole, thus it was not realizable. In the present invention, as the transparent conductive film 8 surely exists under the source line 9b, as shown in FIG. 8A, even if the Ag film disappears, the underlying transparent conductive film 9 can be the source terminal pad. Furthermore as shown in FIG. 8B, instead of the source line 9b, only the transparent conductive film 8 can be the source terminal pad. In this case, the source terminal pad exhibits exceptionally excellent corrosion resistance. Moreover, by adding at least one kind from Pd, Cu, Mo, Nd, Ru, Ge, Au and SnO, to Ag, adherence can be improved.

Additionally, including the present invention, a 4 mask process requires an etching twice more than usual for patterning a source line, source electrode and drain electrode. Especially as a wiring material is easily side-etched, there are numerous disconnections in the source line. In the liquid crystal display according to the present invention, as the transparent conductive film 8 is formed entirely under the source line 9b, even if the source line 9b is disconnected, conductivity can be secured. Accordingly the productivity dramatically improves.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. An active matrix TFT array substrate comprising:
a gate electrode and a gate line formed from a first metal film over a transparent insulating substrate;
a gate insulating film to cover the gate electrode and gate line;
a semiconductor layer formed over the gate insulating film;
a source electrode and a drain electrode formed over the semiconductor layer; and
a pixel electrode formed from a transparent conductive film,
wherein either of the source or the drain electrode is formed from the transparent conductive film and further comprises a second metal film thereover mainly including one of Al, Cu and Ag.

2. The active matrix TFT array substrate according to claim 1, wherein the semiconductor layer includes a semiconductor active film and an ohmic contact film.

3. The active matrix TFT array substrate according to claim 1, wherein the source electrode and the drain electrode are formed from the transparent conductive film and further comprises the second metal film thereover.

4. The active matrix TFT array substrate according to claim 1, wherein the transparent conductive film includes at least one of In₂O₃, SnO₂ and ZnO.

5. The active matrix TFT array substrate according to claim 1, further comprising a pixel reflective electrode formed from the second metal film.

6. A liquid crystal display comprising the active matrix TFT array substrate of claim 1.

7. A method of manufacturing an active matrix TFT array substrate comprising:
forming a gate electrode and a gate line from a first metal film formed over a transparent insulating substrate by a first photolithography process;
sequentially forming a gate insulating film and a semiconductor layer to cover the gate electrode;
patterning the semiconductor layer by a second photolithography process;
sequentially forming a transparent conductive film and a second metal film mainly including one of Al, Cu or Ag;
forming a resist pattern thinner than other area to at least a part of a pixel electrode, etching the second metal film, the transparent conductive film and an ohmic contact film of the semiconductor layer to form a TFT channel and etching the second metal film exposed by removing the thin resist pattern by a third photolithography process;
forming a passivation film; and
forming a contact hole to the gate insulating film and the passivation film penetrating to a surface of the first metal film and a contact hole to the passivation film penetrating to a surface of the transparent conductive film or the second metal film by a forth photolithography process.

8. The method according to claim 7, wherein the transparent conductive film includes at least one of In₂O₃, SnO₂ and ZnO.
